(19) United States
(12) Patent Application Publication
(10) Pub. No.: US 2004/0142560 A1
(43) Pub. Date: Jul. 22, 2004

(54) Method of selective growth of carbon nano-structures on silicon substrates

(76) Inventors: Cheng-Tzu Kuo, Hsinchu (TW); Hui-Lin Chang, Hsinchu (TW); Chao-Hsun Lin, Bade City (TW); Chih-Ming Hsu, Hsinchu (TW)

Correspondence Address: RABIN & BERDO, P.C., 1101 14th Street, N.W., Suite 500, Washington, DC, 20005, US

(21) Appl. No.: 10/345,978

(22) Filed: Jan. 17, 2003

(51) Int. Cl. H01L 21/44

(52) U.S. Cl. 438/682

(57) ABSTRACT

A method of selective growth of carbon nano-structures on silicon substrates, comprising definition of the predetermined area on Si substrates to be grown carbon nano-structures, formation of metal-silicides on the predetermined area on the said Si substrates to be grown carbon nano-structures, and growth of carbon nano-structures on the said metal-silicides by chemical vapor deposition method. Locations of the said metal-silicides on the said Si substrates are growth area of the nano-structures, whereby function of selective growth of carbon nano-structures on Si substrates can be achieved. Besides, the said metal-silicides area is manufactured by semiconductor processes, and is directly compatible with IC processes.

### BACKGROUND OF THE INVENTION

1. Field of the Invention

The invention relates to a growth method of carbon nano-structures on silicon substrates and more particularly to a method of selective growth of carbon nano-structures on silicon substrates.

2. Description of the Prior Art

Since discovery of carbon nanotubes in 1991 by Iijima, the technologies of the nano-materials and their applications, bio-technologies and optoelectronic technologies have become the three major fields in the academic and industrial communities within the last ten years.

The carbon nano-structures, including carbon nanotubes (CNTs) and carbon nanofibers (CNFs), are special cylinder structures with hexagonal carbon lattice and show very unique physical and chemical properties, as follows:

1. High-aspect-ratio more than ˜300.

2. Depending on structural helicity and defects, the carbon nano-structures have numerous potential applications as conductor, semi-conductor and/or super-conductor materials.

3. Superior thermo conductivity (similar to diamond).

4. High Young's modulus: ˜1 terapascals (8 times greater than carbon fiber and 5 times greater than steel).

The synthesis methods of carbon nano-structures generally include, for examples, arch discharge, chemical vapor deposition (CVD) and laser ablation vaporization methods. Wherein the CVD method is the most predominant and has greater potential industrial applications because that carbon structures could be directly deposited on substrates with high yield. Furthermore, the advantage of CVD method used for carbon nano-structures is controllable and deterministic catalytic growth process—that is, the growth location of the carbon nano-structures is precisely determined by the location of catalyst on the substrate.

The current selective growth methods, such as molecular sieving, selective seed implantation, or seed spin coating and sol-gel on the substrate, et al., are difficultly compatible to recent semi-conductor techniques in terms of manufacture process and equipment. Besides, the conventional technique needs an additional process to deposit catalytic membrane on the patterned substrate. Since it is difficult to control the growth on the predetermined locations precisely, it may cause poor selectivity.

With the above-described conventional methods, it is necessary to develop a method of selective growth of carbon nano-structures on silicon substrates, which could achieve to grow carbon nano-structures on the predetermined locations of silicon substrate efficiently and precisely.

### SUMMARY OF THE INVENTION

A primary object of the present invention is to provide a method of selective growth of carbon nano-structures on silicon substrates, of which the metal-silicides are deposited on Si substrates via the semiconductor processing techniques and then the carbon nano-structures are synthesized on the metal-silicides of Si substrates.

To achieve the above object, the method of selective growth of carbon nano-structures on-silicon substrates consists of the following steps:

(a) To define the predetermined area on the Si substrates to be grown the carbon nano-structures via:

(i) depositing a membrane of silicon oxides on the Si substrates, and then

(ii) transferring a masked pattern to Si substrate through semiconductor processing techniques and the said masked pattern defines carbon nano-structures growing area;

(b) To form metal-silicides on predetermined area on the Si substrates to be grown carbon nano-structures via:

(iii) depositing metal membrane;

(iv) forming metal-silicides through rapid thermal process (RTP) and the metal-silicide growing area is the contacting area of the said metal membrane with Si substrate;

(v) chemically etching off the remained metal membrane without previously forming the metal-silicides;

(c) To grow carbon nano-structures on metal-silicides by chemical vapor deposition method.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flowchart of the present invention;

FIG. 2 shows an example of using the present invention;

FIG. 3 shows the typical scanning electron micrographs (SEM) of carbon nanotubes made by the present invention;

FIG. 4 shows the use of carbon nanotubes made by the present invention in semi-conductor devices;

FIG. 5 shows the use of carbon nanotubes made by the present invention in field emission display application.

### DETAILED DESCRIPTION OF THE INVENTION

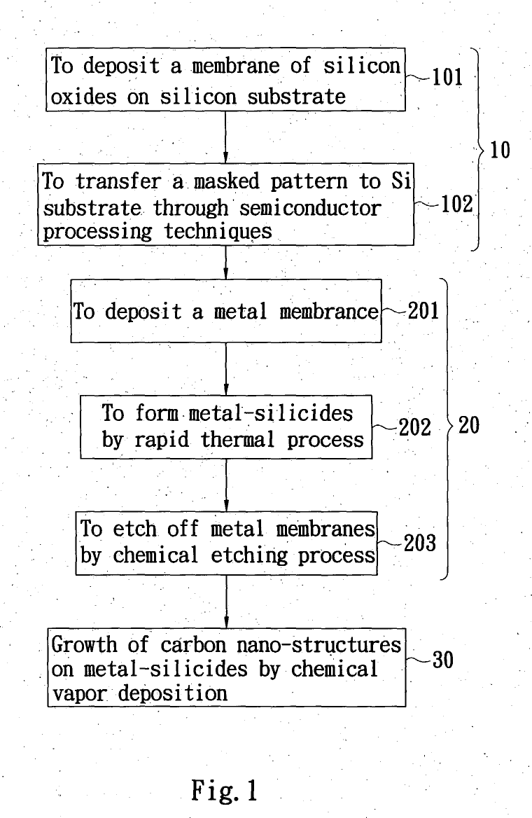

Please refer to a flowchart of the present invention in FIG. 1, including: (a) to define the carbon nano-structures growing area on the Si substrates 10, (b) to form metal-silicides on the defined carbon nano-structures growing area 20, and (c) to grow carbon nano-structures on metal-silicides by chemical vapor deposition method 30.

10 is definition of the predetermined area on the Si substrates to be grown carbon nano-structures, on which 101 a membrane of silicon oxides on silicon substrates is deposited through thermal oxidation or chemical vapor deposition, and then 102 masked pattern is transferred to Si substrates through the semiconductor processing techniques, including photo-resist spin coating and then through photolithography, exposure, development and photo-resist stripping.

20 is formation of metal-silicides on predetermined area on the Si substrates to be grown carbon nano-structures, in, which 201 a metal membrane is deposited on Si substrate first. The material of metal membranes is selected from the group consisting of Iron (Fe), Cobalt (Co), Nickel (Ni), Molybdenum. (Mo), Titanium (Ti), Tungsten (W), Platinum (Pt) or their alloys. The thickness of metal membrane is ranging from 5 Å-1200 Å. Second, 202 metal-silicides are formed by rapid thermal process, wherein only the areas of the metal membrane contacting with Si substrates can react to form metal-silicides. Finally, 203 the remained metal membrane is etched off by chemical etching process and the metal-silicides will remain on Si substrate.

30 is growth of carbon nano-structures on metal-silicides by chemical vapor deposition method, for examples, microwave plasma chemical vapor deposition, electron resonance chemical vapor deposition or thermal chemical vapor deposition. According to chemical vapor deposition method for growing carbon nano-structures, metal is used as catalyst. In other words, growth locations of the carbon nano-structures will be precisely confined to the locations of catalyst on the Si substrate. Thus, procedures 10 and 20 are used to form metal-silicides On the defined locations through a masked pattern, and procedure 30 is used to grow carbon nano-structures on the defined locations with metal-silicides as catalyst.

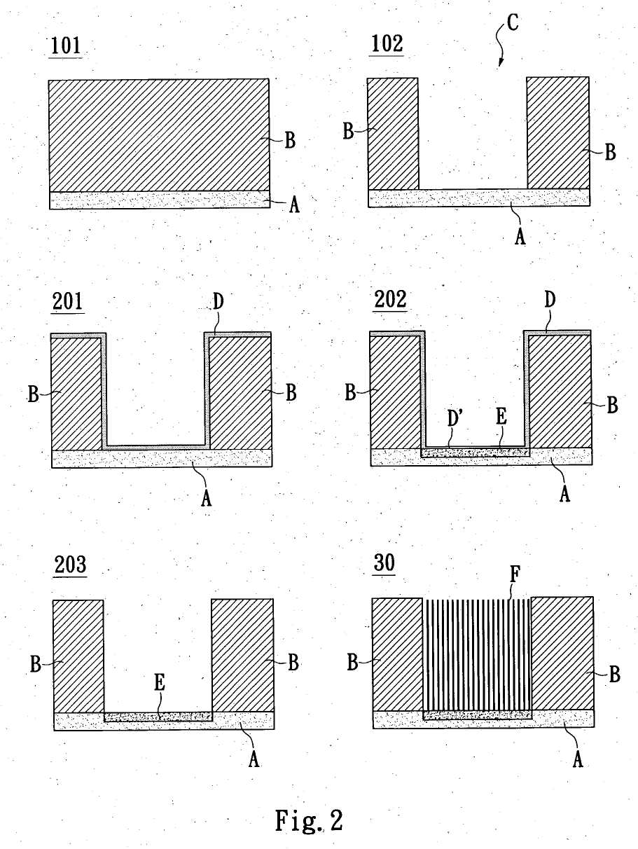

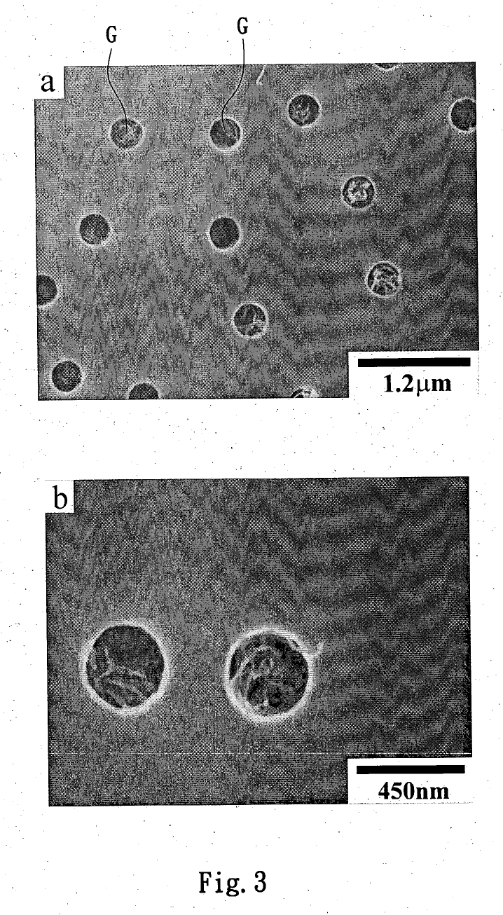

Please refer to FIG. 2 to show the use of the present invention:

(a) Definition of the predetermined area on the Si substrates to be grown carbon nano-structures 10:

Step 101: to deposit a membrane of silicon oxides B on silicon substrate A;

step 102: to transfer a masked pattern C to Si substrate A through semiconductor processing techniques, and the masked pattern C defines the predetermined area on the Si substrates to be grown carbon nano-structures.

(b) formation of metal-silicides on predetermined area on the Si substrates to be grown carbon nano-structures 20:

step 201: to deposit a metal membrane D on the patterned Si substrate A;

step 202: to form metal-silicides E by rapid thermal process, wherein only the contacting area of metal membrane D with Si substrate A will react to form metal-silicides E, besides, the unreacting metal membrane D′ covers on metal-silicides E;

step 203: to etch off metal membranes (D, D′) by chemical etching process and the metal-silicides E will remain on Si substrate.

(c) growth of carbon nano-structures on metal-silicides by chemical vapor deposition method 30: the metal-silicides E are used as the catalyst to grow carbon nano-structures F, only the region of metal silicides E is capable to grow carbon nano-structures F.

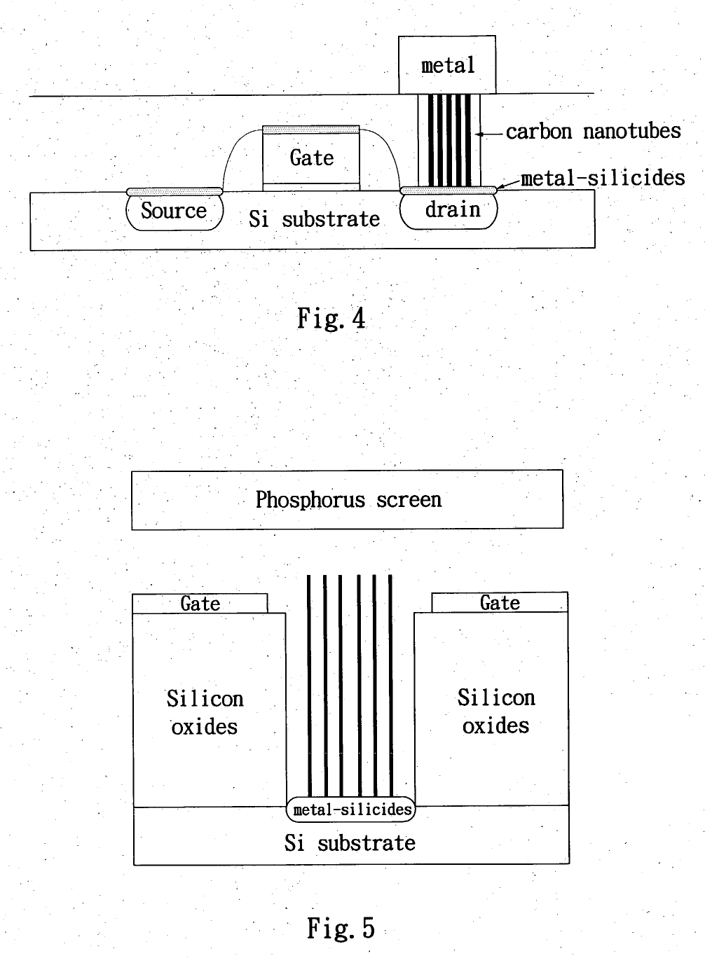

This present invention of using the metal-silicides region to define the growth area of the carbon nano-structures can be directly applied to fabricate the semiconductor devices. For examples, application in MOS (metal oxide silicon) devices (as shown in FIG. 4) and in field emission display devices (as shown in FIG. 5)

As the above mentioned, the method of selective growth of carbon nano-structures on silicon substrates is based on chemical vapor deposition process requiring to use metal-silicides as catalysts to form carbon nano-structures. In other words, the locations with catalysts are the locations deposited by nano-structures, and then the object of selective growth of carbon nano-structures on silicon substrates can be achieved. Furthermore, this present invention is directly compatible with recent semiconductor processes without extra equipments.

The present invention has been described with preferred embodiments thereof and it is understood that many changes and modifications in the described embodiment can be carried out without departing from the scope and the spirit of the invention as defined by the appended claims.

What is claimed:

1. A method of selective growth of carbon nano-structures on silicon substrates, at least comprising:
(a) definition of the predetermined area on Si substrates to be grown carbon nano-structures via:
(i) depositing silicon oxides membrane on the said Si substrates, and then
(ii) transferring a masked pattern to the,said Si substrates through semiconductor processes, and said masked pattern defines the locations of carbon nano-structures growing area:
(b) forming metal-silicides on the predetermined area on the said Si substrate to be grown carbon nano-structures via:
(iii) depositing metal membrane;
(iv) forming metal-silicides through rapid thermal process (RTP) and the metal-silicides growing area is the contacting area of the said metal membrane with the said Si substrate;
(v) etching off the said metal membrane by chemical etching process, and meanwhile the said metal-silicides will remain on Si substrate;
(c) growing carbon nano-structures on area with the said metal-silicides by chemical vapor deposition method.

2. A method of selective growth of carbon nano-structures on silicon substrates as claimed in claim 1, wherein material of the said metal membrane is selected from the group consisting of Iron (Fe), Cobalt (Co), Nickel (Ni), Molybdenum (Mo), Titanium (Ti), Tungsten (W), Platinum (Pt) or their alloys.

3. A method of selective growth of carbon nano-structures on silicon substrates as claimed in claim 1, wherein thickness of the said metal membrane is ranging from 5 Å˜1200 Å.

4. A method of selective growth of carbon nano-structures on silicon substrates as claimed in claim 1, wherein the said chemical vapor deposition method is microwave plasma chemical vapor deposition.

5. A method of selective growth of carbon nano-structures on silicon substrates as claimed in claim 1, wherein the said chemical vapor deposition method is electron resonance chemical vapor deposition.

6. A method of selective growth of carbon nano-structures on silicon substrates as claimed in claim 1, wherein the said chemical vapor deposition method is thermal chemical vapor deposition.
